(19) United States
(12) Patent Application Publication
(10) Pub. No.: US 2026/0229392 A1
(43) Pub. Date: Aug. 6, 2026

(54) IRON NITRIDE MAGNETIC MATERIAL INCLUDING COATED NANOPARTICLES

(71) Applicants: REGENTS OF THE UNIVERSITY OF MINNESOTA, Minneapolis, MN (US); UT-BATTELLE, LLC, Oak Ridge, TN (US); UNIVERSITY OF TENNESSEE RESEARCH FOUNDATION, Knoxville, TN (US)

(72) Inventors: Jian-Ping WANG, Shoreview, MN (US); Yanfeng JIANG, Minneapolis, MN (US); Craig A. BRIDGES, Knoxville, TN (US); Michael P. BRADY, Oak Ridge, TN (US); Orlando RIOS, Knoxville, TN (US); Roberta A. MEISNER, Knoxville, TN (US); Lawrence F. ALLARD, JR., Knoxville, TN (US); Edgar LARA-CURZIO, Lenoir City, TN (US); Shihai HE, Fremont, CA (US)

(21) Appl. No.: 19/634,933

(22) Filed: Mar. 31, 2026

Related U.S. Application Data
(63) Continuation of application No. 17/513,084, filed on Oct. 28, 2021, now Pat. No. 12,620,511.
Application No. 17/513,084 is a division of application No. 15/129,439, filed on Mar. 26, 2015, now Pat. No. 11,195,644.
(60) Provisional application No. 61/971,730, filed on Mar. 28, 2014.

(51) Int. Cl. H01F 1/047; B22F 1/054; C22C 38/00; C23C 14/00; C23C 14/06; C23C 14/16; C23C 14/18; C23C 14/34; C23C 14/56; C23C 14/58; H01F 1/00; H01F 1/06; H01F 41/02

(52) U.S. Cl. CPC H01F 1/047; B22F 1/054; B22F 1/056; C22C 38/001; C22C 38/002; C23C 14/0036; C23C 14/0605; C23C 14/165; C23C 14/185; C23C 14/3414; C23C 14/3464; C23C 14/566; C23C 14/568; C23C 14/5806; C23C 14/586; H01F 1/0054; H01F 1/065; H01F 41/0253; C22C 2202/02

(57) ABSTRACT

The disclosure describes techniques for forming nanoparticles including Fe₁₆N₂ phase. In some examples, the nanoparticles may be formed by first forming nanoparticles including iron, nitrogen, and at least one of carbon or boron. The carbon or boron may be incorporated into the nanoparticles such that the iron, nitrogen, and at least one of carbon or boron are mixed. Alternatively, the at least one of carbon or boron may be coated on a surface of a nanoparticle including iron and nitrogen. The nanoparticle including iron, nitrogen, and at least one of carbon or boron then may be annealed to form at least one phase domain including at least one of Fe₁₆N₂, Fe₁₆(NB)₂, Fe₁₆(NC)₂, or Fe₁₆(NCB)₂.

### CROSS REFERENCE TO RELATED APPLICATIONS

This application is a continuation of U.S. patent application Ser. No. 17/513,084, filed Oct. 28, 2021, which is a divisional of U.S. patent application Ser. No. 15/129,439, filed Sep. 27, 2016, which is a national stage entry under 35 U.S.C. § 371 of International Application No. PCT/US2015/022763, filed Mar. 26, 2015, and claims the benefit of U.S. Provisional Patent Application No. 61/971,730, filed Mar. 28, 2014, all entitled, “IRON NITRIDE MAGNETIC MATERIAL INCLUDING COATED NANOPARTICLES,” the entire contents of which are incorporated by reference herein.

### GOVERNMENT INTEREST

This invention was made with government support under DE-AR0000199 awarded by the U.S. Department of Energy. The government has certain rights in the invention.

### TECHNICAL FIELD

The disclosure relates to iron nitride magnetic materials.

### BACKGROUND

Iron nitride magnets based on the Fe₁₆N₂/Fe₈N phase are of great interest as a magnetic material for applications ranging from data storage to electrical motors for vehicles, wind turbines, and other power generation equipment. The component base elements (Fe, N) are inexpensive and widely available, in contrast to rare earth elements in rare earth element-based magnets, which are costly and subject to supply availability risks. The Fe₁₆N₂ phase, which is the ordered version of Fe₈N, has a large magnetic anisotropy constant and saturation magnetization but is exceedingly difficult to manufacture.

### SUMMARY

The disclosure describes techniques for forming nanoparticles including Fe₁₆N₂ iron nitride phase. In some examples, the nanoparticles may be formed by first forming nanoparticles including iron, nitrogen, and at least one of carbon or boron. The carbon or boron may be incorporated into the nanoparticles such that the iron, nitrogen, and at least one of carbon or boron are mixed. Alternatively, the at least one of carbon or boron may be coated on a surface of a nanoparticle including iron and nitrogen. The nanoparticle including iron, nitrogen, and at least one of carbon or boron then may be annealed to form at least one phase domain including at least one of Fe₁₆N₂, Fe₁₆(NB)₂, Fe₁₆(NC)₂, or Fe₁₆(NCB)₂. In some examples, the nanoparticles may include at least one Fe₁₆N₂ phase domain, and additionally may include at least one phase domain of at least one of Fe₁₆(NB)₂, Fe₁₆(NC)₂, or Fe₁₆(NCB)₂.

In some examples, the nanoparticles including Fe₁₆N₂ iron nitride phase may be formed by forming a nanoparticle including iron and nitrogen, coating the nanoparticle including iron and nitrogen with carbon, boron, or both, and annealing the coated nanoparticle to include at least one Fe₁₆N₂ phase domain. In other examples, the nanoparticles including Fe₁₆N₂ iron nitride phase may be formed by forming an iron nanoparticle coating the iron nanoparticle with carbon, boron, or both. The coated iron nanoparticle then may be nitridized and annealed to form at least one Fe₁₆N₂ phase domain. In some examples, the nanoparticles may include at least one Fe₁₆N₂ phase domain, and additionally may include at least one phase domain of at least one of Fe₁₆(NB)₂, Fe₁₆(NC)₂, or Fe₁₆(NCB)₂.

In one example, the disclosure describes a method including forming a nanoparticle including iron and nitrogen, coating a surface of the nanoparticle with at least one of carbon or boron to form a coated nanoparticle, and annealing the coated nanoparticle to form at least one Fe₁₆N₂ phase domain.

In another example, the disclosure describes a nanoparticle formed by any of the techniques described herein.

In an additional example, the disclosure describes a system configured to perform any of the techniques described herein.

In a further example, the disclosure describes a nanoparticle including a core comprising iron and nitrogen, and a coating comprising at least one of carbon or boron formed on the nanoparticle.

In another example, the disclosure describes a system including a source chamber, a deposition chamber, a loadlock chamber, a first sputtering gun at least partially disposed in the source chamber, a second sputtering gun at least partially disposed in the loadlock chamber, and a substrate transfer mechanism operable to move a substrate between the deposition chamber and the loadlock chamber.

In a further example, the disclosure describes a method including forming a coating comprising at least one of carbon or boron on a surface of a nanoparticle comprising iron to form a coated iron nanoparticle, and nitriding the coated iron nanoparticle by exposing the coated iron nanoparticle to atomic nitrogen to form a nitride nanoparticle, wherein the nitride nanoparticle comprises at least one Fe₁₆N₂ phase domain.

In another example, the disclosure describes a method comprising forming a nanoparticle including iron, nitrogen, and between about 0.5 at. % and about 11 at. % of at least one of carbon or boron; and annealing the nanoparticle to form at least one phase domain comprising at least one of Fe₁₆N₂, Fe₁₆(NB)₂, Fe₁₆(NC)₂, or Fe₁₆(NCB)₂.

The details of one or more examples are set forth in the accompanying drawings and the description below. Other features, objects, and advantages will be apparent from the description and drawings, and from the claims.

### BRIEF DESCRIPTION OF THE DRAWINGS

FIG. 1 is a conceptual and schematic diagram illustrating an example system 10 for forming iron nitride nanoparticles that include a coating including carbon, boron, or both.

FIGS. 2A and 2B show TEM images of sample nanoparticles with and without carbon deposition, respectively.

FIG. 3 is a diagram illustrating a hysteresis loop of magnetic moment versus applied magnetic field of a sample including carbon-coated iron nitride nanoparticles.

FIG. 4 is a diagram illustrating a hysteresis loop of magnetic moment versus applied magnetic field for a sample including uncoated iron nitride nanoparticles.

FIG. 5A is an example XRD image for the sample including carbon-coated nanoparticles.

FIG. 5B is an example plot of intensity versus D-space generated from the XRD image of FIG. 5A.

FIG. 6 is a diagram illustrating x-ray diffraction data for example nitridized nanoparticles.

FIG. 7 is a diagram illustrating hysteresis loops of magnetization versus applied magnetic field at room temperature for example Fe—C precursor nanoparticles after H₂ reduction and after NH₃ nitridation.

FIGS. 8 and 9 are diagrams illustrating composition as a function of depth of example Fe—C precursor nanoparticles and example nanoparticles including Fe₁₆N₂ derived from the Fe—C precursor nanoparticles, respectively.

FIGS. 10A and 10B are micrographs illustrating a plurality of nanoparticles including Fe₁₆N₂ phase and a magnified view of a single nanoparticles including Fe₁₆N₂ phase, respectively.

### DETAILED DESCRIPTION

The disclosure describes techniques for forming nanoparticles including Fe₁₆N₂ iron nitride phase, and for forming iron nitride permanent magnets comprising nanoparticles. In some examples, the nanoparticles may be formed by first forming nanoparticles including iron, nitrogen, and at least one of carbon or boron. In some examples, the nanoparticles may include between about 0.5 at. % and about 11 at. % of at least one of carbon or boron. The carbon or boron may be incorporated into the nanoparticles such that the iron, nitrogen, and at least one of carbon or boron are mixed, forming, for example, at least one of an iron metal phase, an iron carbide phase, an iron boride phase, or an iron carbo-boride phase. Alternatively or additionally, the at least one of carbon or boron may be coated on a surface of a nanoparticle including iron and nitrogen. The nanoparticle including iron, nitrogen, and at least one of carbon or boron then may be annealed to form at least one phase domain including at least one of Fe₁₆N₂, Fe₁₆(NB)₂, Fe₁₆(NC)₂, or Fe₁₆(NCB)₂. In some examples, the nanoparticles may include at least one Fe₁₆N₂ phase domain, and additionally may include at least one phase domain of at least one of Fe₁₆(NB)₂, Fe₁₆(NC)₂, or Fe₁₆(NCB)₂.

In some examples, the nanoparticles including Fe₁₆N₂ iron nitride phase may be formed by forming a nanoparticle including iron, nitrogen, and, optionally, at least one of carbon or boron, coating the nanoparticle with carbon, boron, or both, and annealing the coated nanoparticle to form at least one Fe₁₆N₂ phase domain. In other examples, the nanoparticles including Fe₁₆N₂ iron nitride phase may be formed by forming a nanoparticle including at least one of iron, iron carbide, iron boride, or iron carbo-boride, and, optionally, coating the nanoparticle with carbon, boron, or both. The coated or uncoated nanoparticle that includes at least one of iron, iron carbide, iron boride, or iron carbo-boride then may be nitridized and annealed to form at least one Fe₁₆N₂ phase domain. In some examples, the annealed nanoparticles may include at least one Fe₁₆N₂ phase domain, and additionally may include at least one phase domain of at least one of Fe₁₆(NB)₂, Fe₁₆(NC)₂, or Fe₁₆(NCB)₂.

In some examples, the disclosure describes iron nitride nanoparticles incorporating carbon, boron, or both and techniques for forming iron nitride nanoparticles incorporating carbon, boron, or both. In some examples, the incorporation of carbon, boron, or both in iron nitride nanoparticles may improve magnetic properties of the iron nitride nanoparticles compared to iron nitride nanoparticles that do not incorporate carbon or boron. In some examples, the iron nitride nanoparticles incorporating carbon, boron, or both may be formed by sputtering or another vapor deposition technique. In some examples, iron nitride nanoparticle may be formed, followed by forming a coating of carbon, boron, or both on surfaces of the iron nitride nanoparticles. The coated iron nitride nanoparticles then may be annealed to form at least one Fe₁₆N₂ phase domain. In some examples, the carbon, boron, or both from the coating may diffuse into the iron nitride nanoparticles and be incorporated into the at least one Fe₁₆N₂ phase domain. Incorporation of the carbon, boron, or both into the at least one Fe₁₆N₂ phase domain may result in formation of at least one phase domain of Fe₁₆(NC)₂, Fe₁₆(NB)₂, or Fe₁₆(NCB)₂, respectively.

In some examples, the disclosure describes techniques for forming iron nitride magnetic materials incorporating carbon, boron, or both through the use of carbon or boron coated Fe nanoparticles. In some examples, the carbon or boron coated Fe nanoparticles may be used as a precursor for synthesis of Fe₁₆N₂ phase nanopowder rather than oxide coated or hydroxide coated precursor powders. The carbon or boron coated Fe nanoparticles may improve Fe₁₆N₂ phase yield, magnetic properties, or both in the Fe₁₆N₂ phase nanopowder compared to oxide coated or hydroxide coated precursor powders.

In some examples, the carbon or boron coated Fe₁₆N₂ precursors may include other dopants, including those with ternary and higher order additions to further enhance synthesis yield and magnetic properties, including metals (e.g. Co, Mn, Ni, Co, Cr, Ti, La, other transition metals, and rare earths), as well as oxide coatings such as alumina or silica.

The techniques described herein may be used to form bulk iron nitride permanent magnets. For example, the techniques described herein for forming material comprising nanoparticles having Fe₁₆N₂ iron nitride may be used in processes to form iron nitride bulk permanent magnets described in International Patent Application Number PCT/US2012/051382, filed on Aug. 17, 2012, and titled “IRON NITRIDE PERMANENT MAGNET AND TECHNIQUE FOR FORMING IRON NITRIDE PERMANENT MAGNET;” and International Patent Application Number PCT/US2014/015104, filed on Feb. 6, 2014, and titled “IRON NITRIDE PERMANENT MAGNET AND TECHNIQUE FOR FORMING IRON NITRIDE PERMANENT MAGNET;” and U.S. Provisional Patent Application No. 61/935,516, filed Feb. 4, 2014, and titled “IRON NITRIDE MATERIALS AND MAGNETS INCLUDING IRON NITRIDE MATERIALS,” the entire contents of which are incorporated herein by reference.

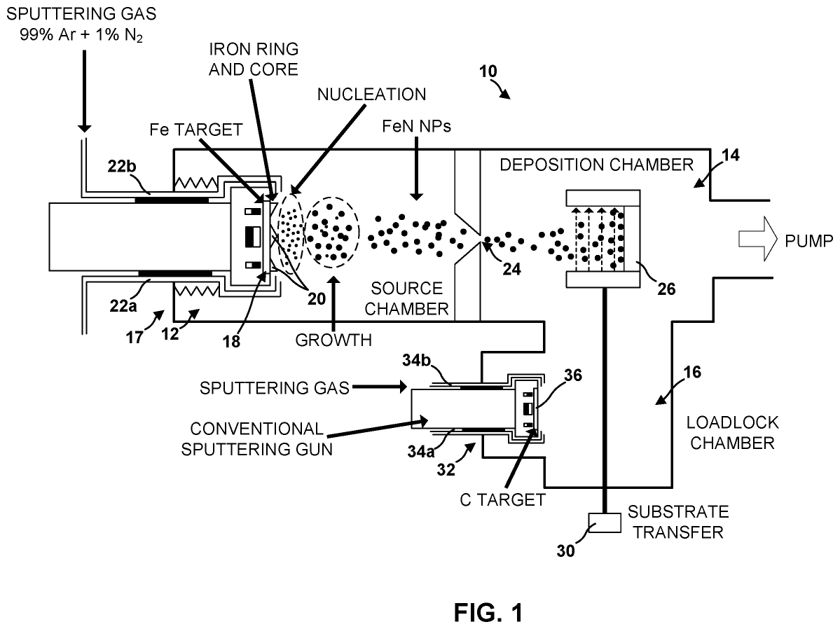

FIG. 1 is a conceptual and schematic diagram illustrating an example system 10 for forming iron nitride nanoparticles that include a coating including carbon, boron, or both. As shown in FIG. 1, system 10 includes a source chamber 12, a deposition chamber 14, and a loadlock chamber 16. Disposed partially within source chamber 12 is a first sputtering gun 17 including sputtering gas inlets 22a and 22b, and an iron target 18 including an iron ring and core 20. In some examples, the iron target 18 including the iron ring and core 20 may include substantially pure iron (e.g., iron with a purity of about 99.99 atomic percent (at. %)).

Source chamber 12 is fluidically coupled to a gas source (not shown in FIG. 1) via sputtering gas inlets 22a and 22b. In some examples, the sputtering gas may include a source of a mixture of argon (Ar) and nitrogen (N₂). For example, the sputtering gas may include a mixture of about 99 atomic percent (at. %) Ar and about 1 at. % N₂. The sputtering gas mixture is excited to high energy, which results in splitting of the N₂ into nitrogen ions. Additionally, the high energy argon atoms impinge upon the iron target 18, which results in iron atoms being ejected from the target 18. This process forms a vapor cloud including active iron and nitrogen atoms in proximity of iron target 18.

In some examples, the sputtering power density used during formation of the iron nitride nanoparticles may be between about 1 watt per centimeter squared (W/cm²) and about 100 W/cm². In some examples, the sputtering pressure during formation of the iron nitride nanoparticles may be between about 10 mTorr (about 1.33 Pascals) and about 2000 mTorr (about 266.66 Pascals), such as between about 200 mTorr (about 26.66 Pascals) and about 500 mTorr (about 66.66 Pascals). In some examples, the base pressure of system 10 may be less than about 1×10⁻⁷ Torr.

The vapor cloud including active iron and nitrogen atoms begins to nucleate to form iron nitride nanoparticles, which continue to grow in size as the nanoparticles and vapor cloud are carried through the source chamber by gas flow of the sputtering gas under influence of a pump. The iron nitride nanoparticles travel through the aperture 24 between source chamber 12 and deposition chamber 14 and are directed at substrate 26, where the iron nitride nanoparticles are deposited. In some examples, the iron nitride nanoparticles define a characteristic dimension, such as a diameter, between about 0.5 nm and about 200 nm, such as between about 0.5 nm and about 50 nm, or between about 5 nm and about 200 nm, or between about 5 nm and about 50 nm. In some examples, a plurality of nanoparticles may include a distribution of characteristic dimensions, the nominal value for the characteristic dimension for the plurality of nanoparticles may be the mean characteristic dimension, the median characteristic dimension, or the like.

Substrate 26 may be coupled to a substrate transfer mechanism 30, which is operable to move substrate 26 between deposition chamber 14 and loadlock chamber 16. After formation of the iron nitride nanoparticles, substrate transfer mechanism 30 may transfer substrate 26 to loadlock chamber, adjacent to second sputtering gun 32. Second sputtering gun 32 is partially disposed in loadlock chamber 16. Second sputtering gun 32 includes sputtering gas inlets 34a and 34b, and a carbon target 36. Sputtering gas inlets 34a and 34b may be fluidically connected to a second sputtering gas source. The second sputtering gas source may include a source of argon gas in some examples.

The high energy argon atoms impinge upon the carbon target 36, which results in carbon atoms being ejected from the target 36. This process forms a vapor cloud including active carbon atoms in proximity of carbon target 36. The carbon atoms may be carried adjacent to the iron nitride nanoparticles deposited on substrate 26, and may at least partially coat surfaces of the iron nitride nanoparticles. In some examples, rather than a carbon target 36, the target may include boron or a mixture of carbon and boron.

In some examples, the sputtering power density used during formation of the iron nitride nanoparticles may be between about 1 W/cm² and about 100 W/cm². In some examples, the sputtering pressure during formation of the iron nitride nanoparticles may be between about 10 mTorr (1.33 Pascals) and about 2000 mTorr (about 266.66 Pascals, such as between about 200 mTorr (about 26.66 Pascals) and about 500 mTorr (about 66.66 Pascals).

The coating including carbon, boron, or both may be deposited to predetermined thickness. In some examples, the predetermined thickness may be between about 5 nanometers (nm) and about 50 nm. In some examples, a coating thickness of less than about 5 nm may have less of an effect on magnetic properties of the annealed iron nitride nanoparticles, or may have substantially no effect on magnetic properties of the annealed iron nitride nanoparticles.

After deposition of the carbon (or boron or both) coating on the iron nitride nanoparticles, the coated iron nitride nanoparticles may be annealed. In some examples, the coated iron nitride nanoparticles may be annealed under vacuum, such as at a pressure under about 5×10⁻⁸ Torr (about 6.66×10⁻⁶ Pa). In some examples, the annealing may be performed at a temperature between about 150° C. and about 250° C., and may be for between about 20 hours and 48 hours. The annealing may form Fe₁₆N₂ phase iron nitride in the coated iron nitride nanoparticles. In some examples, at least some carbon, boron, or both, if present in the coating, may diffuse into the interior of the coated iron nitride nanoparticles during the annealing process.

In some examples, because both the sputtering techniques and the annealing technique are performed in atmospheres substantially free of oxidants, oxidation of the iron nitride nanoparticles may be reduced or substantially prevented. While not wishing to be bound by any theory, reducing or substantially preventing oxidation of the iron nitride particles may contribute to improved magnetic properties of the annealed iron nitride nanoparticles, such as coercivity, magnetization, and the like.

By coating the iron nitride nanoparticles with carbon, boron, or both prior to annealing, the volume fraction of Fe₁₆N₂ phase may be increased compared to an uncoated nanoparticle. By increasing the volume fraction of Fe₁₆N₂ phase, magnetic properties of the annealed iron nitride nanoparticles may be improved, such as coercivity, magnetization, and the like.

Iron nitride nanoparticles may be useful in a wide array of applications. For example, iron nitride nanoparticles may be consolidated to form a bulk material (e.g., a material with a minimum dimension of at least 0.1 mm). As other example, iron nitride nanoparticles may be used in medical and biological applications as particles in sensing applications. By improving magnetic properties of iron nitride nanoparticles, the iron nitride nanoparticles may be used in more applications or may facilitate more effective use in current applications.

The disclosure also describes techniques for utilizing iron nanoparticles including carbon, boron, or both to form iron nitride nanoparticles. In some examples, the iron nanoparticles may be coated with carbon, boron, or both. In some examples, carbon, boron, or both may be mixed with iron in the iron nanoparticles, which may result in at least one of an iron metal, an iron carbide, an iron boride, or an iron carbo-boride phase, with or without one or more oxide phases on a surface of the iron nanoparticles. In some examples, the nanoparticles may include both a core including iron mixed with carbon, boron, or both, and a coating including carbon, boron, or both.

In some examples, in addition to iron and boron, carbon, or both, the iron nanoparticles may include oxygen. For example, at least some iron in the iron nitride nanoparticles may be oxidized.

In some examples, the iron nanoparticles may include other dopants as an alternative to or in addition to oxygen. For example, the iron nanoparticles may include at least one metal dopant, such as Co, Mn, Cr, Ni, Ti, La, other transition metals, and/or a rare earth element. As another example, the iron nanoparticles may include at least one oxide dopant, such as alumina or silica, which may be mixed with the iron or may be a coating on the iron nanoparticles. The iron nanoparticles may define a range of sizes, such as a mean or median diameter between about 20 nm and about 40 nm.

In some examples, such as when the iron nanoparticles include an oxide, the iron nanoparticles may be exposed to a reducing species to reduce the oxide. For example, the iron nanoparticles may be exposed to a reducing gas, such as H₂, at a temperature between about 200° C. and about 500° C. for up to about 10 hours to reduce oxides present on or in the iron nanoparticles. In some examples, the iron nanoparticles may not include oxides (e.g., due to the presence of a coating including carbon, boron, or both on surfaces of the iron nanoparticles). In some of these examples, the iron nanoparticles may not be exposed to the reducing step. In some examples, eliminating the reducing step may reduce powder sintering, which may contribute to enhanced magnetic properties.

The iron nanoparticles including at least one of carbon or boron may be nitridized by exposure to a nitrogen source. In some examples, the nitrogen source may include ammonia (NH₃), such as substantially pure gaseous ammonia or a gaseous mixture of ammonia, nitrogen, and hydrogen. In other examples, urea may be used as a nitrogen source.

In some examples, the iron nanoparticles may be nitridized by exposure to a nitrogen source at a temperature between about 100° C. and about 200° C. for up to about 1 week.

After nitridization, the iron nanoparticles may include a mixture of iron, nitrogen, at least one of carbon or boron, and any other dopants present in the iron nanoparticles. At least some of the iron and nitrogen may form an Fe₁₆N₂ phase. Other phases also may be present in the iron nanoparticles after nitridization, such as Fe phase, iron oxides, other iron nitrides (such as Fe₈N, Fe₄N, Fe₃N, or the like), iron carbides or borides, as well as B, C, and/or doped Fe₁₆N₂ phase.

Optionally, the nitridized nanoparticles may be annealed. In some examples, the nitridized nanoparticles may be annealed under vacuum, such as at a pressure under about 5×10⁻⁸ Torr (about 6.66×10⁻⁶ Pa). In some examples, the annealing may be performed at a temperature between about 150° C. and about 250° C., and may be for between about 20 hours and 48 hours. The annealing may form Fe₁₆N₂ phase iron nitride in the coated iron nitride nanoparticles. In some examples, the annealing may form at least one phase domain including at least one of Fe₁₆(NB)₂, Fe₁₆(NC)₂, or Fe₁₆(NCB)₂ in addition to the Fe₁₆N₂ phase iron nitride. In some examples, at least some carbon, boron, or both, if present in the coating, may diffuse into the interior of the coated iron nitride nanoparticles during the annealing process.

In some examples, use of iron nanoparticles including at least one of carbon or boron may increase a percentage of the nanoparticle that includes Fe₁₆N₂ phase after nidridization compared to using other precursor materials, such as iron oxide nanoparticles. The increase in Fe₁₆N₂ phase may contribute to improved magnetic properties, such as coercivity, magnetization, and the like.

Clause 1: In some examples, the disclosure describes a method comprising: forming a nanoparticle including iron and nitrogen; coating a surface of the nanoparticle with at least one of carbon or boron to form a coated nanoparticle; and annealing the coated nanoparticle to form at least one Fe₁₆N₂ phase domain.

Clause 2: The method of clause 1, wherein forming the nanoparticle comprises: directing an energized sputtering gas at a target comprising iron to form an iron vapor; forming atomic nitrogen vapor; and condensing iron atoms from the iron vapor and nitrogen atoms from the atomic nitrogen vapor to form the nanoparticle including iron and nitrogen.

Clause 3: The method of clause 1, wherein the sputtering gas comprises argon and diatomic nitrogen, and wherein the atomic nitrogen vapor is formed from the diatomic nitrogen.

Clause 4: The method of any one of clauses 1 to 3, wherein a sputtering power density used while forming the nanoparticle is between about 1 W/cm² and about 100 W/cm², and wherein a sputtering pressure used while forming the nanoparticle is between about 26.66 Pascals and about 66.66 Pascals.

Clause 5: The method of any one of clauses 1 to 4, wherein the nanoparticle comprises a plurality of nanoparticles.

Clause 6: The method of any one of clauses 1 to 5, wherein coating the surface of the nanoparticle comprises: directing an energized sputtering gas at a target comprising the at least one of carbon or boron to form a vapor comprising atoms of the at least one of carbon or boron; and condensing the atoms of the at least one of carbon or boron from the vapor to form the coated nanoparticle.

Clause 7: The method of clause 6, wherein the at least one of carbon or boron comprises carbon.

Clause 8: The method of clause 6 or 7, wherein the sputtering gas comprises argon.

Clause 9: The method of any of clauses 1 to 8, wherein a sputtering power density used while coating the surface of the nanoparticle is between about 1 W/cm² and about 100 W/cm², and wherein a sputtering pressure used while coating the surface of the nanoparticle is between about 26.66 Pascals and about 66.66 Pascals.

Clause 10: The method of any of clauses 1 to 9, wherein the coated nanoparticle comprises a coating including the at least one of carbon or boron, and wherein a thickness of the coating is between about 0.5 nanometers and about 50 nanometers.

Clause 11: The method of any of clauses 1 to 10, wherein annealing the coated nanoparticle to form the at least one Fe₁₆N₂ phase domain comprises annealing the coated nanoparticle to form the at least one Fe₁₆N₂ phase domain at a temperature between about 150° C. and about 250° C. for between about 20 hours and 48 hours.

Clause 12: A nanoparticle formed by the method of any of clauses 1 to 11.

Clause 13: A system configured to perform the method of any of clauses 1 to 11.

Clause 14: In some examples, the disclosure describes a nanoparticle comprising: a core comprising iron and nitrogen; and a coating comprising at least one of carbon or boron formed on the nanoparticle.

Clause 15: The nanoparticle of clause 14, wherein the nanoparticle comprises at least one Fe₁₆N₂ phase domain.

Clause 16: The nanoparticle of clause 14 or 15, wherein the at least one of carbon or boron comprises carbon.

Clause 17: The nanoparticle of any of clause 14 to 16, wherein the coating defines a thickness between about 0.5 nanometers and about 50 nanometers.

Clause 18: In some examples, the disclosure describes a bulk magnetic material comprising: a plurality of consolidated nanoparticles, wherein at least one of the plurality of consolidated nanoparticles comprises the nanoparticle of any of clauses 14 to 17.

Clause 19. In some examples, the disclosure describes a system comprising: a source chamber; a deposition chamber; a loadlock chamber; a first sputtering gun at least partially disposed in the source chamber; a second sputtering gun at least partially disposed in the loadlock chamber; and a substrate transfer mechanism operable to move a substrate between the deposition chamber and the loadlock chamber.

Clause 20: The system of clause 19, wherein the first sputtering gun comprises a first target material comprising iron positioned to be impinged upon by a first sputtering gas provided by the first sputtering gun.

Clause 21: The system of clause 20, wherein the first sputtering gas comprises a gaseous mixture of argon and diatomic nitrogen.

Clause 22: The system of any of clauses 19 to 21, wherein the second sputtering gun comprises a second target material comprising at least one of carbon or boron positioned to be impinged upon by a second sputtering gas provided by the second sputtering gun.

Clause 23: The system of any of clauses 19 to 22, further comprising the substrate, wherein the substrate is coupled to the substrate transfer mechanism and receives iron nitride nanoparticles formed using the first sputtering gun.

Clause 24: In some examples, the disclosure describes a method comprising: forming a coating comprising at least one of carbon or boron on a surface of a nanoparticle comprising iron to form a coated iron nanoparticle; and nitriding the coated iron nanoparticle by exposing the coated iron nanoparticle to atomic nitrogen to form a nitride nanoparticle, wherein the nitride nanoparticle comprises at least one Fe₁₆N₂ phase domain.

Clause 25: The method of clause 24, wherein forming the coating comprising at least one of carbon or boron on the surface of the nanoparticle comprises forming the coating comprising carbon on the surface of the nanoparticle.

Clause 26: The method of clause 24 or 25, wherein the coated iron nanoparticle further comprises at least one metal dopant, at least one oxide dopant, or both.

Clause 27: The method of clause 26, wherein the at least one metal dopant comprises at least one of a transition metal or a rare earth metal.

Clause 28: The method of clause 26, wherein the at least one oxide dopant comprises at least one of iron oxide, aluminum oxide, or silicon oxide.

Clause 29: The method of any of clauses 24 to 28, wherein the nanoparticle defines a diameter between about 20 nm and about 40 nm.

Clause 30: The method of any of clauses 24 to 29, wherein nitriding the coated iron nanoparticle comprises exposing the nanoparticle to gaseous ammonia.

Clause 31: The method of clause 30, wherein exposing the nanoparticle to gaseous ammonia comprises exposing the nanoparticle to gaseous ammonia at a temperature between about 100° C. and about 200° C. for up to about 1 week.

Clause 32: The method of any of clauses 24 to 31, further comprising, prior to nitriding the coated iron nanoparticle, exposing the coated iron nanoparticle to a reducing gas.

Clause 33: The method of clause 32, wherein the reducing gas comprises hydrogen gas.

Clause 34: The method of clause 32 or 33, wherein exposing the coated iron nanoparticle to the reducing gas comprises exposing the coated iron nanoparticle to the reducing gas at a temperature between about 200° C. and about 500° C. for up to about 10 hours.

Clause 35: The method of any of clauses 24 to 34, wherein the nanoparticle comprises a plurality of nanoparticles.

Clause 36: In some examples, the disclosure describes a system for performing the method of any of clauses 24 to 35.

Clause 37: In some examples, the disclosure describes a nanoparticle formed by the method of any of clauses 24 to 35.

Clause 38: In some examples, the disclosure describes an iron nitride permanent magnet comprising nanoparticles coated with carbon or boron.

Clause 39: The iron nitride permanent magnet of clause 38, wherein the iron nitride permanent magnet comprises at least one Fe₁₆N₂ phase domain.

Clause 40: The iron nitride permanent magnet of clause 38, wherein the iron nitride permanent magnet comprises a bulk permanent magnet having a minimum dimension of at least 0.1 mm.

Clause 41: In some examples, the disclosure describes a method comprising: forming a nanoparticle including iron, nitrogen, and between about 0.5 at. % and about 11 at. % of at least one of carbon or boron; and annealing the nanoparticle to form at least one phase domain comprising at least one of Fe₁₆N₂, Fe₁₆(NB)₂, Fe₁₆(NC)₂, or Fe₁₆(NCB)₂.

Clause 42: The method of clause 41, wherein forming the nanoparticle including iron, nitrogen, and between about 0.5 at. % and about 11 at. % of at least one of carbon or boron comprises: forming a nanoparticle including iron and nitrogen; and coating a surface of the nanoparticle with at least one of carbon or boron to form a coated nanoparticle.

Clause 43: The method of clause 42, wherein forming the nanoparticle comprises: directing an energized sputtering gas at a target comprising iron to form an iron vapor; forming atomic nitrogen vapor; and condensing iron atoms from the iron vapor and nitrogen atoms from the atomic nitrogen vapor to form the nanoparticle including iron and nitrogen.

Clause 44: The method of clause 43, wherein the sputtering gas comprises argon and diatomic nitrogen, and wherein the atomic nitrogen vapor is formed from the diatomic nitrogen.

Clause 45: The method of any of clauses 42 to 44, wherein the coated nanoparticle comprises a coating including the at least one of carbon or boron, and wherein a thickness of the coating is between about 0.5 nanometers and about 50 nanometers.

Clause 46: The method of any of clauses 42 to 45, wherein annealing the coated nanoparticle to form the at least one Fe₁₆N₂ phase domain comprises annealing the coated nanoparticle to form the at least one Fe₁₆N₂ phase domain at a temperature between about 150° C. and about 250° C. for between about 20 hours and 48 hours.

Clause 47: The method of clause 42, wherein forming the nanoparticle including iron, nitrogen, and between about 0.5 at. % and about 11 at. % of at least one of carbon or boron comprises: forming a coating comprising at least one of carbon or boron on a surface of a nanoparticle comprising iron to form a coated iron nanoparticle; and nitriding the coated iron nanoparticle by exposing the coated iron nanoparticle to atomic nitrogen.

Clause 48: The method of clause 47, wherein the coated iron nanoparticle further comprises at least one metal dopant, at least one oxide dopant, or both.

Clause 49: The method of clause 48, wherein the at least one metal dopant comprises at least one of a transition metal or a rare earth metal.

Clause 50: The method of clause 48, wherein the at least one oxide dopant comprises at least one of iron oxide, aluminum oxide, or silicon oxide.

Clause 51: The method of any of clauses 47 to 50, wherein nitriding the coated iron nanoparticle comprises exposing the nanoparticle to gaseous ammonia.

Clause 52: The method of clause 51, wherein exposing the nanoparticle to gaseous ammonia comprises exposing the nanoparticle to gaseous ammonia at a temperature between about 100° C. and about 200° C. for up to about 1 week.

Clause 53: The method of any of clauses 47 to 62, further comprising, prior to nitriding the coated iron nanoparticle, exposing the coated iron nanoparticle to hydrogen.

Clause 54: In some examples, the disclosure describes a system for performing the method of any of clauses 42 to 53.

Clause 55: In some examples, the disclosure describes a nanoparticle formed by the method of any of clauses 42 to 53.

Clause 56: In some examples, the disclosure describes a bulk permanent magnet comprising a plurality of nanoparticles formed by the method of any of clauses 42 to 53, wherein a minimum dimension of the bulk permanent magnet is at least 0.1 mm.

### EXAMPLES

### Example 1

The system illustrated in FIG. 1 was used to prepare iron nitride particles coated with carbon. The base pressure of system 10 was below 1×10⁻⁷ Torr. Fe targets with 99.99 at % purity were used as the sputtering target 18, and a sputtering gas including a mixture of 99 at. % argon and 1 at. % nitrogen was used as. The sputtering gas was injected into the source chamber 12 and a gas flow was formed flying from source chamber 12 to deposition chamber 14. During fabrication, N₂ molecules were split into active nitrogen atoms by high energy argon ions and electrons. At the same time, Fe atoms were knocked out of the target 18 by the bombardment of high energy argon ions. As a result, a vapor mixture of Fe and N atoms was formed in the proximity of Fe target 18. The Fe atoms condensed together with the N atoms to form iron nitride nanoparticles. The formed iron nitride nanoparticles were carried by gas flow and travel from the source chamber 12 to the deposition chamber 14. The iron nitride nanoparticles deposited on substrate 26. Based on this synthesis process, the composition of the FeN nanoparticles was precisely controlled by adjusting the percentage of N₂ in the sputtering gas. The sputtering current and pressure were fixed at between about 0.2 A and about 0.7 A and between about 200 mTorr and about 500 m Torr, respectively.

Carbon deposition was followed in the same system, with carbon target 36 having a 99.99 at. % purity. Highly pure argon was used as the sputtering gas. The flow rate of the sputtering gas was between about 20 standard cubic centimeter per minute (seem) and about 50 seem. The sputtering current was between about 0.2 A and about 0.7 A while the pressure was between about 200 mTorr and about 500 mTorr.

After formation of the carbon-coated iron nitride nanoparticles, the carbon-coated iron nitride nanoparticles were annealed at a temperature between about 150° C. and about 250° C. for between about 20 hours and about 48 hours in a vacuum chamber with a base pressure below 5×10⁻⁸ Torr.

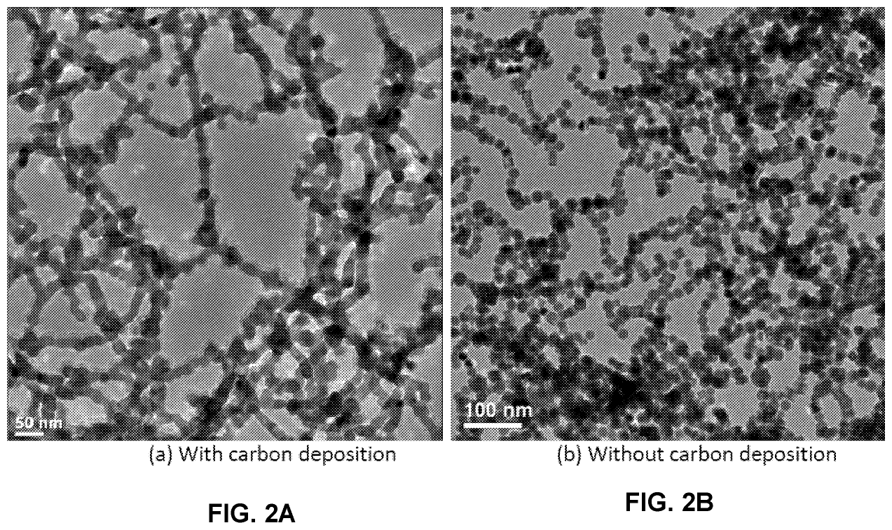

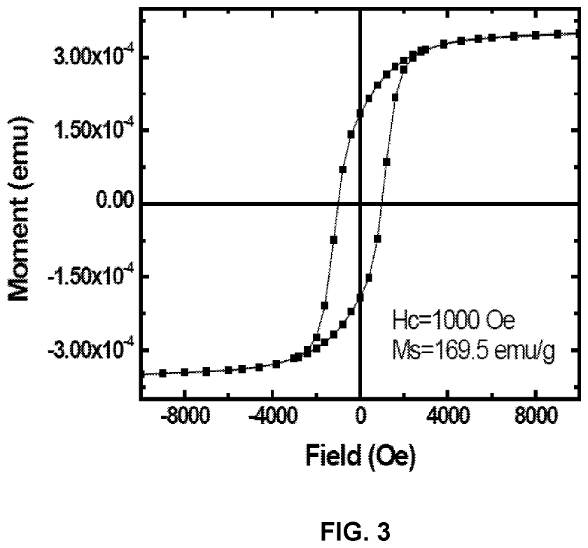

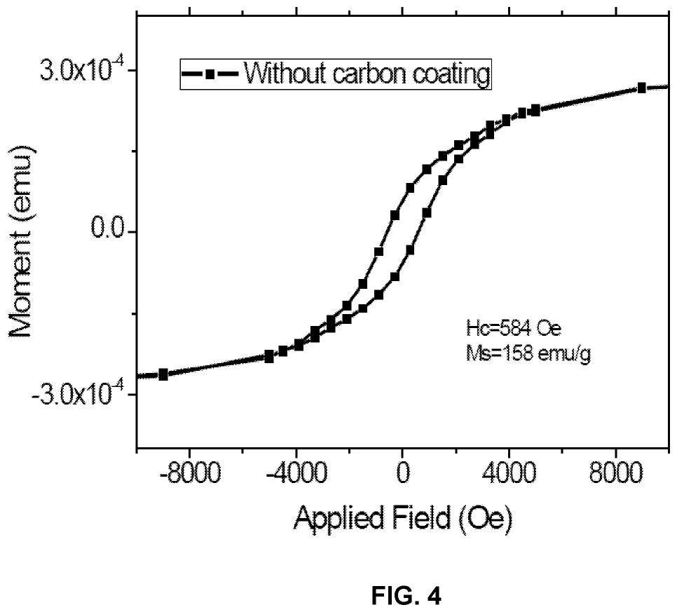

Transmission Electron Microscopy (TEM) was used to characterize the obtained nanoparticles. FIGS. 2A and 2B show TEM images of sample nanoparticles with and without carbon deposition, respectively. For the sample without carbon deposition, its nanoparticles are distributed substantially homogeneous and separately. Without carbon deposition, the coercivity of the nanoparticles was about 200 Oe. For the sample with carbon deposition, as shown in FIG. 2A, after annealing, the nanoparticles were deformed and combined with each other to from unified strings. The coercivity of the sample with carbon-coated nanoparticles was about 1000 Oe. FIG. 3 shows the hysteresis loop of magnetic moment versus applied magnetic field of the sample including carbon-coated nanoparticles. FIG. 4 shows the hysteresis loop of magnetic moment versus applied magnetic field for the sample including uncoated nanoparticles.

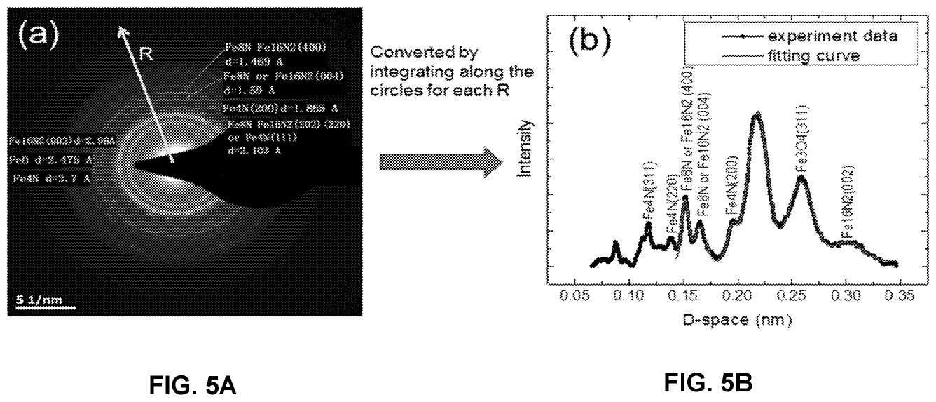

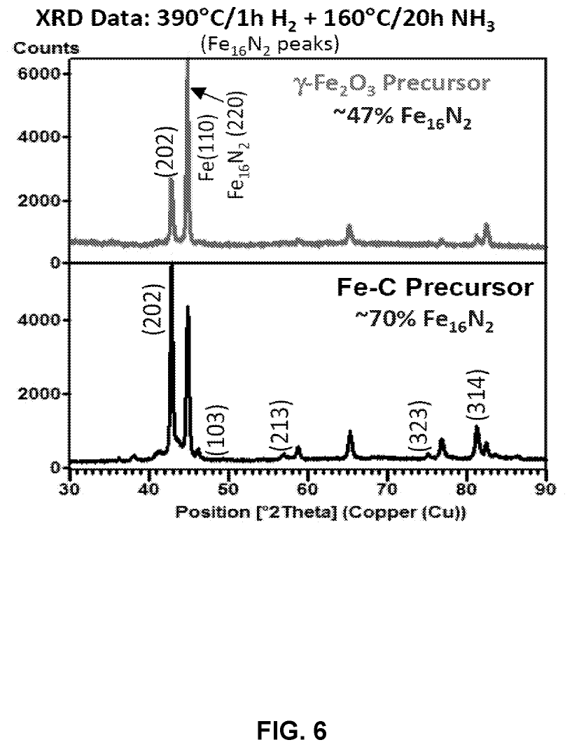

The volume ratio of Fe₁₆N₂/Fe₈N phase was estimated for the sample including carbon-coated nanoparticles. FIG. 5A is an example XRD image for the sample including carbon-coated nanoparticles. FIG. 5B is an example plot of intensity versus D-space generated from the XRD image of FIG. 5A. The peak intensities for Fe₁₆N₂ and Fe₈N, Fe₄N, and Fe₃O₄ were determined by integrating the respective circles for each radius. The results of the integrations are shown in Table 1.

TABLE 1

| | Fe₁₆N₂ and Fe₈N | | |
|---|---|---|---|
| | (202) | Fe₄N(111) | Fe₃O₄(311) |
| Peak intensity | 2138 | 309 | 540 |
| Volume ratio | 66% | 11.6% | 22.4% |

The volume ratio of Fe₁₆N₂ and Fe₈N, Fe₄N, and Fe₃O₄ were then determined by determining the ratio of the peak intensities. The volume ratio of Fe₁₆N₂ and Fe₈N was estimated to be 66% for the carbon-coated nanoparticles.

The surface coverage of Fe₁₆N₂/Fe₈N was estimated to be about 77.6% based on the TEM image shown in FIG. 2A, and the saturation magnetization of the sample was estimated to be 170 emu/g based on the hysteresis loop. To make a comparison, FIG. 4 shows the hysteresis loop of magnetic moment versus applied magnetic field for a sample including iron nitride particles without a carbon coating. For the sample including uncoated iron nitride particles, the coercivity was about 584 Oe and the saturation magnetization was estimated to be 158 emu/g with 82% coverage based on the TEM image shown in FIG. 2B.

### Example 2

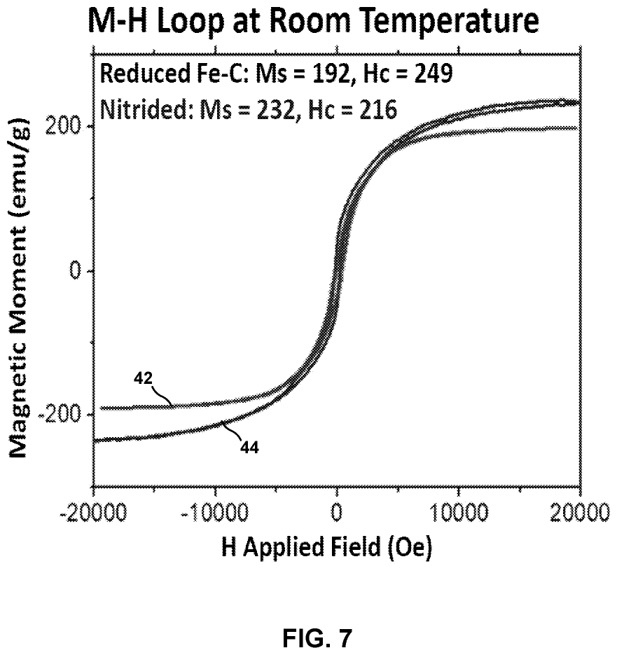

A γ-Fe₂O₃ precursor powder with nanoparticle diameters between about 20 nm and about 40 nm and a surface area of between about 30 m²/g and about 60 m²/g was reduced at a temperature of about 390° C. for about 1 hour in substantially pure H₂. The T-Fe₂O₃ precursor powder is available from Alfa Aesar, Ward Hill, Massachusetts. The reduced iron nanoparticles were then nitrided at a temperature of about 160° C. for about 20 hours in an atmosphere of substantially pure gaseous NH₃. FIG. 6 is a diagram illustrating x-ray diffraction data for the nitrided nanoparticles.

A passivated (includes oxygen) Fe—C precursor powder with nanoparticle diameters of about 25 nm and a surface area of between about 40 m²/g and about 60 m²/g was reduced at a temperature of about 390° C. for about 1 hour in substantially pure H₂. The Fe—C precursor powder is reported to contain nominal C levels of about 8.66 weight percent (wt. %) and nominal 0 levels of about 10 wt. %. The reduced Fe—C nanoparticles were then nitrided at a temperature of about 160° C. for about 20 hours in an atmosphere of substantially pure gaseous NH₃. FIG. 6 is a diagram illustrating x-ray diffraction data for the nitrided nanoparticles. The top diagram in FIG. 5 illustrates the x-ray diffraction data for the nitrided γ-Fe₂O₃ nanoparticles. The bottom diagram in FIG. 5 illustrates the x-ray diffraction data for the nitrided Fe—C nanoparticles. The Fe₁₆N₂ phase yield for the γ-Fe₂O₃ precursor powder was about 47% under these conditions, compared with about 70% Fe₁₆N₂ phase yield using the Fe—C precursor nanoparticles. Tables 2 and 3 list the estimated phase percentages for various phases in the nitrided nanoparticles.

TABLE 2
Phase percentages for γ-Fe₂O₃ precursor powder

| Phase | Percentage (%) |
|---|---|
| Fe₁₆N₂ | 47 |
| Fe | 47 |
| Fe₃O₄ | 1 |
| Fe₄N | 5 |
| Fe₃N | 0 |

TABLE 3
Phase percentages for Fe—C precursor powder

| | Percentage |
|---|---|
| Phase | (%) |
| Fe₁₆N₂ | 71 |
| Fe | 17 |
| Fe₃O₄ | 0 |
| Fe₄N | 4 |
| Fe₃N/Fe₃C | 8 |

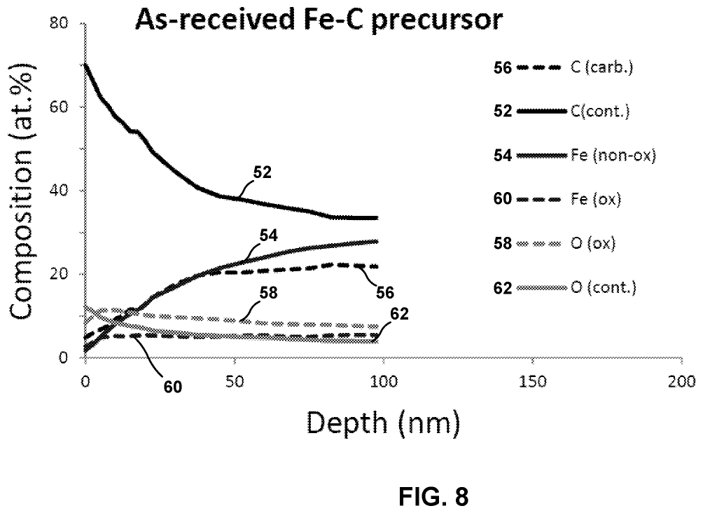

FIG. 7 is a diagram illustrating hysteresis loops of magnetization versus applied magnetic field at room temperature for Fe—C precursor nanoparticles after H₂ reduction and after NH₃ nitridation. As shown in FIG. 7, after H₂ reduction, the Fe—C precursor nanoparticles (curve 42) reached a magnetization value of about 192 emu/gram at a field of 20 kOe and a coercivity of about 249 Oe. After nitridation, the nitrided powder (curve 44) reached a magnetization value of about 232 emu/gram at a field of 20 kOe and a coercivity of about 216 Oe. For comparison, the Fe₁₆N₂ containing nanoparticles derived from γ-Fe₂O₃ nanoparticles exhibited a magnetization of only 207 emu/gram at room temperature, only marginally exceeding the nominal value of 200 emu/g for pure iron.

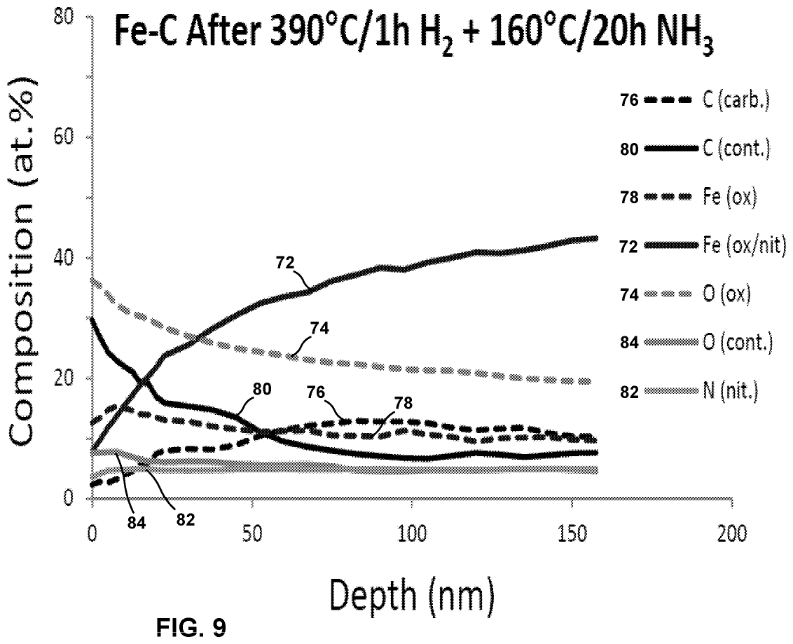

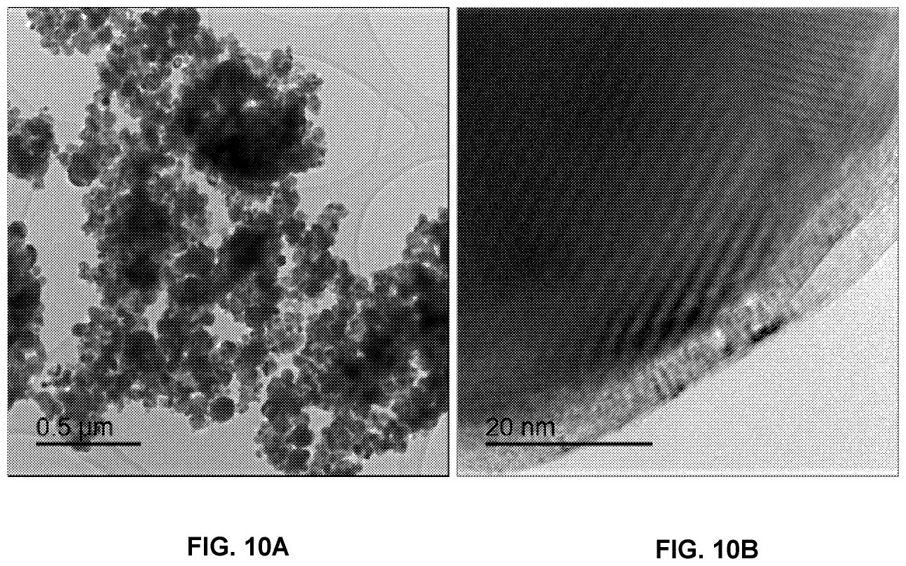

Tables 4 and 5 present results powder analysis by bulk combustion technique for C and N content. FIGS. 8 and 9 are diagrams illustrating composition as a function of depth of the Fe—C precursor nanoparticles and the nanoparticles including Fe₁₆N₂ derived from the Fe—C precursor nanoparticles. The composition data in FIGS. 8 and 9 was measured using x-ray photoelectron spectroscopy (XPS) sputtering techniques. The XPS technique was based on sputtering into a range of agglomerated reaction powders to a depth at which the composition profiles leveled out. FIGS. 10A and 10B are micrographs illustrating a plurality of nanoparticles including Fe₁₆N₂ phase and a magnified view of a single nanoparticles including Fe₁₆N₂ phase. As shown in FIG. 10A, the nitrided powders had a range of particle sizes, such that the XPS sputtering data presented in FIGS. 8 and 9 should be considered semi-quantitative rather than quantitative, as it is effectively averaged over particle surfaces and interiors. Significant C is retained in the resultant nitrided powders, with TEM data indicating a graphitic carbon coating was retained (FIG. 10B) and XPS data suggesting both nitride and carbide bonding. These features may contribute to the relatively high Fe₁₆N₂ phase yield and magnetization values, and suggest the possibility of both nitride and carbon-nitride formation. Such formation is consistent with similarities in the Fe—C and Fe—N system, particularly with regards to both C and N resulting in Fe martensite formation (Fe₈N disordered is essentially a martensitic phase). The XPS data shown in FIGS. 8 and 9 also indicate that significant oxygen was present in the nitrided nanoparticles. This oxygen may aid stability of the nanoparticles in air. The conversion between weight percent and atomic percent in Table 4 is based on the assumption that the precursor and nanoparticles include only iron, carbon, and nitrogen.

TABLE 4
Powder composition analysis by combustion technique

| | C content | N content |
|---|---|---|
| Material | wt. % (at. %) | wt. % (at. %) |
| Fe—C precursor | 4.94 | <0.023 |
| | (19.35) | (<0.77) |
| Nitrided nanoparticles | 1.3 | 2.82 |
| | (5.34) | (9.94) |

TABLE 5
Powder composition analysis by x-ray photoelectron
spectroscopy technique

| | C content | N content | 0 content |
|---|---|---|---|
| Material | at. % | at. % | at. % |
| Fe—C precursor | 46.6 | — | 16.2 |
| Nitrided | 18.7 | 5.0 | 23.2 |
| nanoparticles | | | |

Various examples have been described. These and other examples are within the scope of the following claims.

What is claimed is:

1. An iron nitride permanent magnet comprising:
a plurality of consolidated nanoparticles, wherein at least one of the plurality of consolidated nanoparticles comprises:
a core comprising at least one Fe₁₆N₂ phase domain; and
a dopant comprising Cr.

2. The permanent magnet of claim 1, further comprising a coating of Cr.

3. The permanent magnet of claim 1, further comprising an Mn dopant.

4. The permanent magnet of claim 2, further comprising a coating of Mn.

5. The permanent magnet of claim 1, wherein the iron nitride permanent magnet material has a minimum dimension of at least 0.1 mm.

6. The permanent magnetic material of claim 2, wherein the coating defines a thickness between about 0.5 nanometers and about 50 nanometers, and wherein the nanoparticles comprises diameters between about 0.5 nm and about 200 nm.

7. An iron nitride permanent magnet formed from a precursor comprising an iron nanoparticle and a Cr dopant.

8. The iron nitride permanent magnet of claim 7, further comprising an Mn dopant.
